(19) United States
(12) Patent Application Publication
(10) Pub. No.: US 2024/0332465 A1
(43) Pub. Date: Oct. 3, 2024

(54) MANUFACTURING METHOD OF DISPLAY PANEL, MANUFACTURING METHOD OF SPLICING SCREEN, AND DISPLAY DEVICE

(71) Applicant: Shenzhen China Star Optoelectronics emiconductor Display Technology Co., Ltd., Shenzhen (CN)

(72) Inventor: Linshuang Li, Shenzhen (CN)

(21) Appl. No.: 17/610,523

(22) PCT Filed: Sep. 24, 2021
(86) PCT No.: PCT/CN2021/120081

§ 371 Date: May 18, 2024

(30) Foreign Application Priority Data
Sep. 10, 2021 (CN) 202111059247.7

(51) Int. Cl. H01L 33/56; H01L 25/16; H01L 33/48

(52) U.S. Cl. CPC H01L 33/56; H01L 25/167; H01L 33/483; H01L 2933/005

(57) ABSTRACT

A manufacturing method of a display panel, a manufacturing method of a splicing screen, and a display device are provided, which relates to the technical field of manufacturing display devices. In the present disclosure, when a backplane and a cover are packaged, a supporting wall is first disposed so that the supporting wall, the backplane, and cover together enclose a cavity to be injected for accommodating a light emitting device, and then a packaging adhesive is injected. It reduces a thickness error of the packaging adhesive in the display panel, and reduces a thickness difference of the packaging adhesive in different display panels to be spliced.

### FIELD OF DISCLOSURE

The present disclosure relates to the technical field of manufacturing display devices, and more particularly to a manufacturing method of a display panel and a display device.

### BACKGROUND

In comparison with traditional organic light-emitting diode (OLED) and light-emitting diode (LCD) display technologies, mini-LED or micro-LED display technologies have lower power consumption, faster response time, and higher image resolution and color gamut.

However, due to a size of mini-LED or micro-LED display panel, a current large-size mini-LED or micro-LED display device is mainly formed by splicing multiple display panels. In the prior art, the mini-LED or micro-LED display panel mainly uses a packaging adhesive and a glass cover to package light emitting devices. The packaging adhesive is directly formed on a backplane, and a thickness of the packaging adhesive is difficult to control. This leads to differences in the thickness of the packaging adhesive in different display panels. Moreover, the lack of support ability of the packaging adhesive for the cover will further enlarge the thickness difference of the display panels, which will affect display performance of the splicing screen and the display device.

### SUMMARY OF DISCLOSURE

### Technical Problem

The technical problem to be solved by the present disclosure is to provide a manufacturing method of a display panel, a manufacturing method of a splicing screen, and a display device, which can reduce a thickness error of a packaging adhesive.

### Solutions to the Problem

### Technical Solutions

Technical solutions adopted by the present disclosure to solve the above technical problem are:

In a first aspect, the present disclosure provides a manufacturing method of a display panel, which includes steps of:
providing a backplane, wherein a light emitting device is disposed on one surface of the backplane;
providing a cover opposite to the backplane, and disposing a supporting wall between the backplane and the cover, wherein the supporting wall, the backplane, and the cover enclose a cavity to be injected for accommodating the light emitting device; and
injecting a packaging adhesive into the cavity to be injected and curing the packaging adhesive to form the display panel.

Alternatively, in some embodiments of the present disclosure, the step of providing the cover opposite to the backplane, and disposing the supporting wall between the backplane and the cover, wherein the supporting wall, the backplane, and the cover enclose the cavity to be injected for accommodating the light emitting device, includes:
providing the cover, and disposing the supporting wall on one surface of the cover;
making the surface of the cover provided with the supporting wall opposite to the surface of the backplane provided with the light emitting device; and
making the supporting wall in contact with the surface of the backplane provided with the light emitting device, wherein the cover and the backplane are separated by a predetermined distance by the supporting wall, and the supporting wall, the backplane, and the cover enclose the cavity to be injected for accommodating the light emitting device.

Alternatively, in some embodiments of the present disclosure, the surface of the backplane includes a display area and a non-display area surrounding the display area, and the light emitting device is disposed on the display area.

The step of making the supporting wall in contact with the surface of the backplane provided with the light emitting device includes:
making the supporting wall in contact with the surface of the backplane provided with the light emitting device, wherein a projection of the supporting wall on the backplane is covered by the non-display area.

Alternatively, in some embodiments of the present disclosure, the display area is a rectangle, and the supporting wall is a frame shape with a square inner hole.

Alternatively, in some embodiments of the present disclosure, the display area is circular, and the supporting wall is an annulus with an inner hole.

Alternatively, in some embodiments of the present disclosure, the supporting wall includes a base and a filter filled in the base.

Alternatively, in some embodiments of the present disclosure, a material hardness of the filter is greater than a material hardness of the base.

Alternatively, in some embodiments of the present disclosure, the filter is one of an irregular particle, a square particle, and a polyhedral particle.

Alternatively, in some embodiments of the present disclosure, the filter is a sphere.

Alternatively, in some embodiments of the present disclosure, a spherical diameter of the filter is 0.4 to 0.6 times the predetermined distance.

Alternatively, in some embodiments of the present disclosure, the spherical diameter of the filter is 0.5 times the predetermined distance.

Alternatively, in some embodiments of the present disclosure, material of the base includes epoxy resin, methyl methacrylate, or silica gel, and material of the filter includes SiO₂ or alumina.

Alternatively, in some embodiments of the present disclosure, a width of a cross section of the supporting wall in a direction perpendicular to the cover gradually decreases from a side close to the cover to another side far away from the cover.

Alternatively, in some embodiments of the present disclosure, the cross section of the supporting wall in the direction perpendicular to the cover is trapezoidal.

Alternatively, in some embodiments of the present disclosure, a shape of a cross section of the supporting wall in a direction perpendicular to the cover is one or a combination of a rectangle, a circle, a triangle, a trapezoid, and a T-shape.

Alternatively, in some embodiments of the present disclosure, the step of providing the backplane, wherein the light emitting device is disposed on the surface of the backplane, including:
providing a substrate, wherein the substrate includes a first surface;
disposing a thin film transistor layer on the first surface to form the backplane; and
disposing the light emitting device on a surface of the thin film transistor layer facing away from the first surface.

Alternatively, in some embodiments of the present disclosure, the light emitting device is a mini-light-emitting-diode (LED) chip or a micro-LED chip.

Alternatively, in some embodiments of the present disclosure, the thin film transistor layer has a top gate structure.

In a second aspect, the present disclosure provides a manufacturing method of a splicing screen, including the display panel manufacturing method as described in the first aspect, and further including steps of:
removing the supporting wall after forming the display panel to form a borderless display panel; and
splicing a plurality of borderless display panels to form the splicing screen.

Alternatively, in some embodiments of the present disclosure, the step of removing the supporting wall after forming the display panel to form the borderless display panel including:
removing the supporting wall by cutting the supporting wall after forming the display panel to form the borderless display panel.

In a third aspect, the present disclosure provides a display device. The display device is manufactured by using the manufacturing method of the display panel as described in the first aspect, or is manufactured by using the manufacturing method of the splicing screen as described in the second aspect.

### Beneficial Effects of the Disclosure

### Beneficial Effects

In comparison with the prior art, embodiments of the present disclosure have following advantages:

The present disclosure discloses a manufacturing method of a display panel, a manufacturing method of a splicing screen, and a display device, and relates to the technical field of manufacturing display devices. The manufacturing method of the display panel, the manufacturing method of the splicing screen, and the display device provided by the present disclosure mainly improve a packaging process of the backplane and the cover. In the embodiments of the present disclosure, when the backplane and the cover are packaged, the supporting wall is disposed between the two, so that the supporting wall, the backplane, and the cover together enclose the cavity to be injected for accommodating the light emitting device. Then, the packaging adhesive is injected. Since the supporting wall is supported between the backplane and the cover, the packaging adhesive formed in the cavity to be injected after curing can maintain a relatively stable film thickness. It reduces a thickness error of the packaging adhesive in the display panel, thereby reducing the difference in the thickness of the packaging adhesive in different display panels to be spliced, and improving the uniformity of thicknesses the packaging adhesives.

### BRIEF DESCRIPTION OF DRAWINGS

### Description of Drawings

In order to more clearly describe the technical solutions in the embodiments of the present disclosure or the prior art, the following briefly introduces the drawings that need to be used in the embodiments. The drawings in the following description are only some embodiments of the present disclosure. For those of ordinary skill in the art, without creative efforts, other drawings can be obtained based on these drawings.

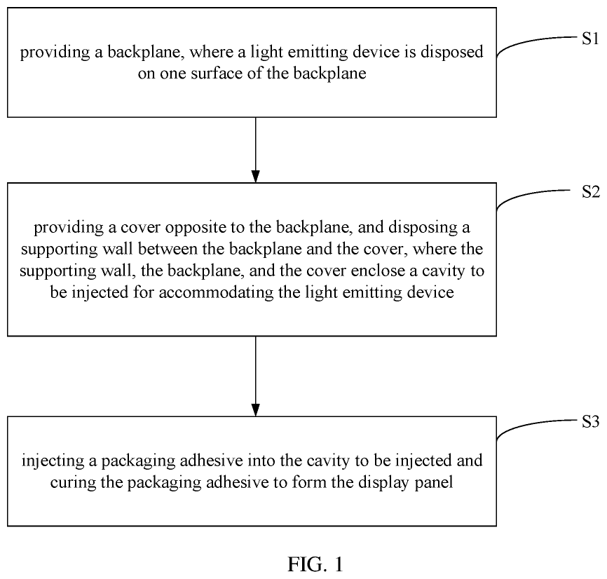

FIG. 1 is a flowchart of a manufacturing method of a display panel of an Embodiment 1 of the present disclosure.

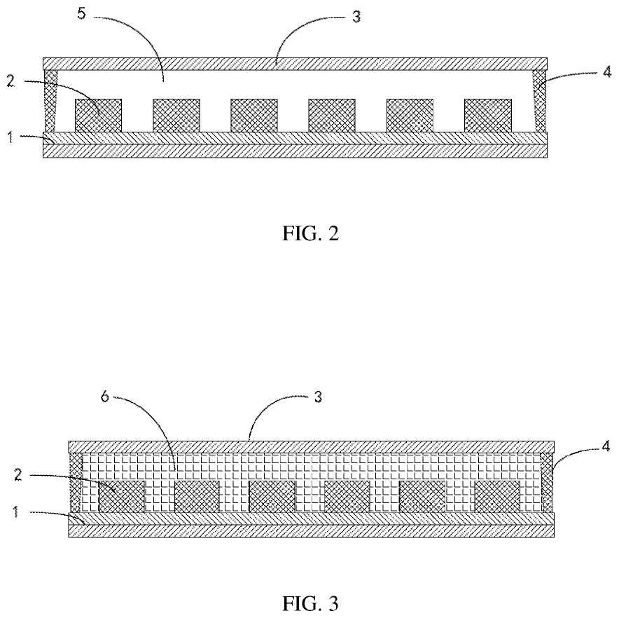

FIG. 2 is a schematic diagram of a step S2 of the Embodiment 1 of the present disclosure.

FIG. 3 is a schematic diagram of a step S3 of the Embodiment 1 of the present disclosure.

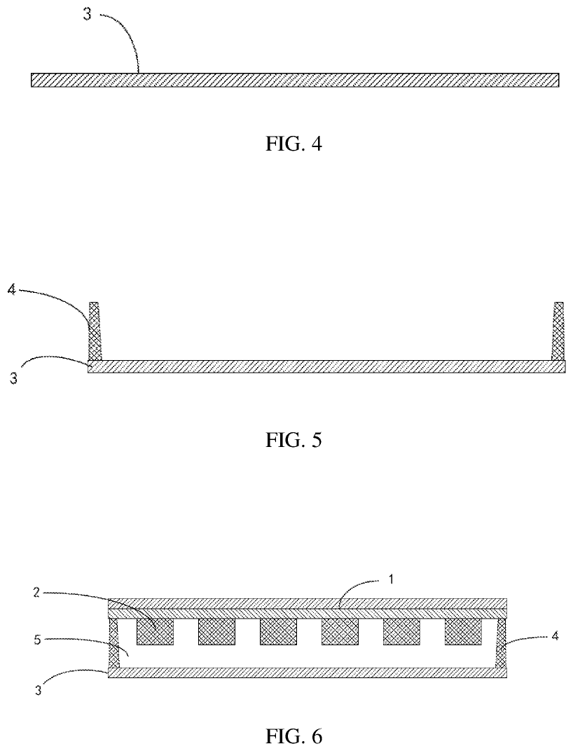

FIG. 4 and FIG. 5 are schematic diagrams of a step S201 of an Embodiment 2 of the present disclosure.

FIG. 6 is a schematic diagram of a step S203 of the Embodiment 2 of the present disclosure.

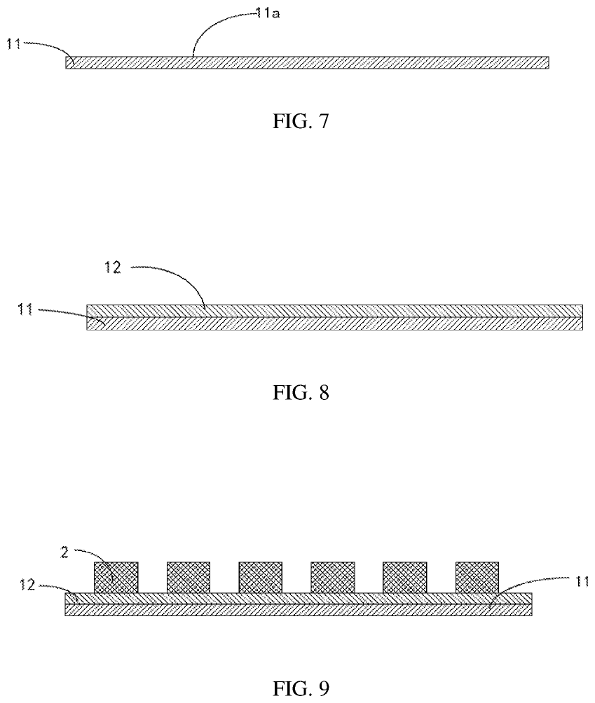

FIG. 7 is a schematic diagram of a step S101 of the Embodiment 2 of the present disclosure.

FIG. 8 is a schematic diagram of a step S102 of the Embodiment 2 of the present disclosure.

FIG. 9 is a schematic diagram of a step S103 of the Embodiment 2 of the present disclosure.

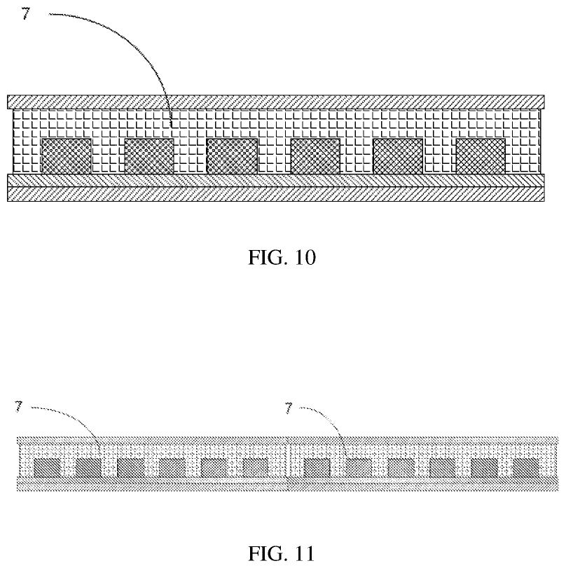

FIG. 10 is a schematic diagram of a step S4 of an Embodiment 3 of the present disclosure.

FIG. 11 is a schematic diagram of a step S5 of the Embodiment 3 of the present disclosure.

### DETAILED DESCRIPTION

### Embodiments of the Disclosure

The technical solutions in the embodiments of the present disclosure will be described clearly and completely below in conjunction with accompanying drawings in the embodiments of the present disclosure. Apparently, the embodiments described are some but not all embodiments of the present disclosure. Generally, components in the embodiments of the present disclosure, as described and shown in the accompanying drawings herein, may be arranged and designed in various different configurations. Therefore, the detailed description below of the embodiments of the present disclosure provided in the accompanying drawings is not intended to limit the claimed scope of the present disclosure, but merely represents chosen embodiments of the present disclosure. All other embodiments obtained by those ordinarily skilled in the art based on the embodiments of the present disclosure without any creative efforts shall fall within the scope of protection of the present disclosure.

It should be noted that similar reference numerals and letters represent similar items in the following accompanying drawings, therefore, once a certain item is defined in one accompanying drawing, it is not needed to be further defined or explained in subsequent accompanying drawings. Also, in the description of the present disclosure, the terms “first”, “second”, etc. are only used to distinguish the description, and cannot be understood as indicating or implying relative importance.

An embodiment 1 provides a manufacturing method of a display panel. Referring to FIG. 1, which is a flowchart of the manufacturing method of the display panel of this embodiment. In this embodiment, the manufacturing method of the display panel includes steps of:

S1, a backplane 1 is provided. A light emitting device 2 is disposed on one surface of the backplane 1.

S2, a cover 3 opposite to the backplane 1 is provided, and a supporting wall 4 is disposed between the backplane 1 and the cover 3. The supporting wall 4, the backplane 1, and the cover 3 enclose a cavity to be injected 5 for accommodating the light emitting device 2.

S3, a packaging adhesive 6 is injected into the cavity to be injected 5 and the packaging adhesive 6 is cured to form the display panel.

Referring to FIG. 2 and FIG. 3, in the manufacturing method of the display panel of the embodiment, and in the step S2, the supporting wall 4 is disposed between the backplane 1 and the cover 3. The supporting wall 4 uses its own supporting characteristics to support the backplane 1 and the cover 3, and the supports wall 4, the backplane 1, and the cover 3 together enclose the cavity to be injected 5 for accommodating the light emitting device 2. Sequentially, the packaging adhesive 6 is injected into the cavity to be injected Sand the packaging adhesive 6 is cured to cover the light emitting device 2, thereby completing a packaging process of the display panel.

The manufacturing method of the display panel in this embodiment mainly implements the packaging of the display panel by arranging the supporting wall 4 with a certain supporting capacity. The supporting characteristics of the supporting wall 4 can effectively ensure that a distance between the backplane 1 and the cover 3 is within an expected range, and can ensure a thickness tolerance of the packaging adhesive 6 in a final formed display panel. Thus, the thickness difference of the packaging adhesive in different display panels to be spliced is reduced, a uniformity of the thickness of the packaging adhesive is improved, and the display performance of the display panel spliced by the display panels is improved.

It should be noted that the manufacturing method of the display panel provided above can reduce the error of the thickness of the packaging adhesive 6 in the display panel, so the uniformity of the thickness of the packaging adhesive 6 in each display panel to be spliced of the splicing screen can be improved. It can be understood that the above-mentioned manufacturing method of the display panel is not limited to manufacturing the display panel to be spliced, and it can also be used to manufacture an independent display panel.

This specific implementation manner also provides an embodiment 2. A main difference between the embodiment 2 and the embodiment 1 is that the embodiment 2 refines the step S2.

Referring to FIG. 4, FIG. 5, and FIG. 6, in the embodiment 2, the step S2 of providing the cover 3 opposite to the backplane 1, and disposing the supporting wall 4 between the backplane 1 and the cover 3, where the supporting wall 4, the backplane 1, and the cover 3 enclose the cavity to be injected 5 for accommodating the light emitting device 2, includes:
S201, the cover 3 is provided, and the supporting wall 4 is disposed on one surface of the cover 3.
S202, the surface of the cover 3 provided with the supporting wall 4 is opposite to the surface of the backplane 1 provided with the light emitting device 2.
S203, the supporting wall 4 is in contact with the surface of the backplane 1 provided with the light emitting device 2. The cover 3 and the backplane 1 are separated by a predetermined distance by the supporting wall 4. The supporting wall 4, the backplane 1, and the cover 3 enclose the cavity to be injected 5 for accommodating the light emitting device 2.

Regarding the step S201, in some embodiments, the supporting wall 4 is first formed on the backplane 1, and then the supporting wall 4 is in contact with the cover 3 through the change of the relative position between the backplane 1 and the cover 3.

In this embodiment, the supporting wall 4 is directly formed on the cover 3 in the step S201. With such a configuration, the process of disposing the supporting wall 4 on the cover 3 and the process of manufacturing the backplane 1 can be performed simultaneously, thereby improving production efficiency.

Regarding the step S202, in this embodiment, the backplane 1 is turned over after the light emitting device 2 is disposed, so that a side where the light emitting device 2 is disposed faces the cover 3 arranged below. In the step S202, an implementer may also set the backplane 1 on a lower side, and set the cover 3 on an upper side, which is not particularly limited in the present disclosure.

Regarding the step S203, the predetermined distance refers to a stable distance that the supporting wall 4 can separate the backplane 1 and the cover 3 after being in contact with the backplane 1 and the cover 3. After the supporting wall 4 is in contact with the backplane 1 and the cover 3, a size of the supporting wall 4 in a direction from the backplane 1 to the cover 3 is the same, and the predetermined distance is also the same as the thickness of the cured and formed packaging adhesive 6.

It should be noted that the backplane 1 includes a display area and a non-display area surrounding the display area. The light emitting device 2 is disposed in the display area and used as a display component. In the above steps, a contact part between the supporting wall 4 and the backplane 1 can be disposed in the display area, as long as the supporting wall 4 can accommodate the light emitting device 2. In this embodiment, a projection of the supporting wall 4 on the backplane 1 is covered by the non-display area, so as to prevent the supporting wall 4 from contacting the display area of the backplane 1, to maximize an injection range of the packaging adhesive 6, and to avoid affecting the display of the display panel.

It can be understood that the above supporting wall 4 is in a shape with an inner hole. An inner hole wall of the supporting wall 4 is a portion of the enclosed cavity to be injected 5. A specific shape of the supporting wall 4 can be determined according to the change of the display area of the display panel. For example, in this embodiment, the display area of the display panel has a rectangular shape, and the supporting wall 4 correspondingly has a frame shape with a square inner hole. In another embodiment, the display area of the display panel has a circular shape, and the supporting wall 4 correspondingly has an annulus with an inner hole.

Furthermore, for the supporting wall 4, the supporting ability of the supporting wall 4 determines the thickness of the packaging adhesive 6 between the backplane 1 and the cover 3. The supporting wall 4 can be made of resin only as shown in the embodiment 1. However, using resin alone as the supporting wall 4, the supporting wall 4 has limited supporting capacity, and it is difficult to ensure that the backplane 1 and cover 3 can be stably separated by the predetermined distance. Therefore, in order to improve the supporting ability of the supporting wall 4 itself, in this embodiment, the supporting wall 4 includes a base and a filter filled in the base. The filter can fill voids in the base due to the process and its own structure, thereby effectively improving support performance of the supporting wall 4, so that the backplane 1 and the cover 3 can be stably separated by the predetermined distance, which further guarantees the thickness of the packaging adhesive 6 between the backplane 1 and the cover 3.

In addition, implementers can also configure a material hardness of the filter to be greater than a material hardness of the base as shown in this embodiment, so as to further improve the supporting performance of the supporting wall 4. In this embodiment, the base is made of epoxy resin, and the filter is made of SiO₂. Implementers can specifically select materials of the base and the filter based on their own needs. For example, in another embodiment, the base is made of methyl methacrylate, and the filter is made of alumina particles. Implementers can also use materials such as silica gel to form the base, and use other metal particles or non-metal particles to form the filter.

In addition, the above-mentioned filter may have a shape such as irregular particle, square particle, polyhedral particle, etc. In this embodiment, in order to further improve the support performance of the filter for the base, the filter is a sphere, and a spherical diameter of the filter is 0.4 to 0.6 times the predetermined distance, and can alternatively be half of the predetermined distance.

It should be noted that implementers can choose the shape of the supporting wall 4 according to their own needs. For example, after the supporting wall 4 is disposed on the cover 3, a cross section of the supporting wall 4 in a direction perpendicular to the cover 3 can be any one of rectangle, circle, triangle, trapezoid, T-shaped, and a combination of several.

In this embodiment, refer to FIG. 5, after the supporting wall 4 is disposed on one side of the cover 3, a width of the cross section of the supporting wall 4 in the direction perpendicular to the cover 3 gradually decreases from the side close to the cover 3 to another side far away from the cover 3. It is understandable that the supporting wall 4 with such the cross-section has better supporting performance than the supporting wall 4 with a circular cross-sectional shape. In this embodiment, the above-mentioned cross section is specifically trapezoidal. A longer side of the trapezoid is connected to the cover 3, while a shorter side is facing away from the cover 3. Furthermore, it can be understood that the aforementioned width refers to a size of the supporting wall 4 in a direction parallel to the cover 3.

Referring to FIG. 7, FIG. 8, and FIG. 9, implementers can further refine the step S1. For example, in this embodiment, the step S1 of providing the backplane 1 and disposing the light emitting device 2 on one side of the backplane 1 includes:
S101, a substrate 11 is provided. The substrate 11 includes a first surface 11a.
S102, a thin film transistor layer 12 is disposed on the first surface 11a to form the backplane 1.
S103, the light emitting device 2 is disposed on a surface of the thin film transistor layer 12 away from the first surface 11a.

The above-mentioned light emitting device 2 may be a mini-LED chip or a micro-LED chip. In this embodiment, the micro-LED chip is taken as an example, but it should not be understood as a limitation on the light emitting device 2. The prior art has already disclosed some technical means for mass transferring mini-LED chips or micro-LED chips to the thin film transistor layer 12, so it will not be repeated here. Furthermore, a size of the mini-LED chip (i.e., its thickness) in the direction from the backplane 1 to the cover 3 can be selected at 100±15 um. A size of the micro-LED chip (i.e., its thickness) in the direction from the backplane 1 to the cover 3 can be selected at 8±3 um. To ensure the supporting performance of the supporting wall 4, a height of the supporting wall 4 (i.e., the predetermined distance that the backplane 1 and the cover 3 can be separated under the support of the supporting wall 4) can be 1.5 to 2 times the thickness of the mini-LED chip or the micro-LED chip. In addition, in this embodiment, the thin film transistor layer 12 may be a top gate structure, but it may also be any structure such as a bottom gate structure. An active layer in the thin film transistor layer 12 can be IGZO, IGTO, IGZTO, and other high-mobility metal oxide semiconductors, and implementers can choose correspondingly according to their own needs.

Regarding the step S3, in this embodiment, after the cavity to be injected 5 is injected with the packaging adhesive 6, the packaging adhesive 6 needs to be cured to complete the packaging process of the display panel. In this embodiment, the packaging adhesive 6 is cured by UV light.

Implementers can also use a process of thermal curing or UV light curing combined with thermal curing, which is not particularly limited in the present disclosure.

It should be pointed out that the packaging adhesive 6 can be selected as silicone or epoxy adhesive, its light transmittance should be greater than 95%, and its viscosity is less than 1000 cp to ensure the display performance and packaging performance of the display panel.

This specific implementation manner also provides a manufacturing method of a splicing screen as an embodiment 3.

Referring to FIG. 10 and FIG. 11, the manufacturing method of the splicing screen provided in this embodiment includes the manufacturing method of the display panel as described in the embodiment 1, which further includes steps of:
S4, the supporting wall 4 is removed after forming the display panel to form a borderless display panel 7.
S5, a plurality of borderless display panels 7 are spliced to form the splicing screen.

In the manufacturing method of the splicing screen of this embodiment, after the display panel is formed, the supporting wall 4 is removed and processed to obtain the borderless display panel. After the plurality of borderless display panels 7 are obtained, the plurality of borderless display panels 7 can be laid flat and aligned and spliced to obtain the splicing screen.

Regarding the removal process of the supporting wall 4, implementers can use a cutting method to separate the supporting wall 4 from the cured packaging adhesive 6. Implementers can also select other removal processes according to the specific material of the supporting wall 4, which is not particularly limited in the present disclosure.

In addition, the manufacturing method of the splicing screen provided in this embodiment is not limited to the assembling of two borderless display panels 7 shown in this embodiment, and it can also be used for splicing between a plurality of borderless display panels 7. For example, splicing multiple borderless display panels 7 such as 3 pieces, 4 pieces, etc. The prior art has already disclosed some splicing methods between the borderless display panels 7, and this embodiment will not describe the splicing methods between the borderless display panels 7, and implementers can choose correspondingly according to their own needs.

This specific embodiment also provides a display device. The display device is manufactured using the manufacturing method of the display panel provided in the embodiment 1 or the embodiment 2, or manufactured using the manufacturing method of the splicing screen provided in the embodiment 3. The display devices include but are not limited to mobile phones, tablet, computer monitors, game consoles, televisions, wearable devices, and other household appliances or household appliances with display functions.

The present disclosure provides the manufacturing method of the display panel, the manufacturing method of the splicing screen, and the display device. By setting the supporting wall 4 to support the backplane 1 and the cover 3, and the supporting performance of the supporting wall 4 is optimized and improved. It is ensured that the thickness of the packaging adhesive 6 is within the expected range during packaging, thereby improving the uniformity of the thickness of the packaging adhesive 6 in each display panel to be spliced, and ensuring the display performance of the splicing screen and the display device.

The display panel and the manufacturing method thereof provided by the present disclosure are described in detail above. It is understood that the exemplary embodiments described herein are to be considered as illustrative only, are used to help understand the method and core idea of the present disclosure, and are not intended to limit the present disclosure. Descriptions of features or aspects in each exemplary embodiment should generally be considered as suitable features or aspects in other exemplary embodiments. While the present disclosure has been described with reference to the preferred embodiments thereof, various modifications and changes can be made by those skilled in the art. The present disclosure is intended to cover such modifications and modifications within the scope of the appended claims. Any modification, equivalent replacements, and improvements, etc., made within the spirit and principles of the present disclosure, shall be included in the protection scope of the present disclosure.

1. A manufacturing method of a display panel, comprising steps of:
providing a backplane, wherein a light emitting device is disposed on one surface of the backplane;
providing a cover opposite to the backplane, and disposing a supporting wall between the backplane and the cover, wherein the supporting wall, the backplane, and the cover enclose a cavity to be injected for accommodating the light emitting device; and
injecting a packaging adhesive into the cavity to be injected and curing the packaging adhesive to form the display panel.

2. The manufacturing method of the display panel according to claim 1, wherein the step of providing the cover opposite to the backplane, and disposing the supporting wall between the backplane and the cover, wherein the supporting wall, the backplane, and the cover enclose the cavity to be injected for accommodating the light emitting device, comprises:
providing the cover, and disposing the supporting wall on one surface of the cover;
making the surface of the cover provided with the supporting wall opposite to the surface of the backplane provided with the light emitting device; and
making the supporting wall in contact with the surface of the backplane provided with the light emitting device, wherein the cover and the backplane are separated by a predetermined distance by the supporting wall, and the supporting wall, the backplane, and the cover enclose the cavity to be injected for accommodating the light emitting device.

3. The manufacturing method of the display panel according to claim 2, wherein the surface of the backplane comprises a display area and a non-display area surrounding the display area, and the light emitting device is disposed on the display area; and
wherein the step of making the supporting wall in contact with the surface of the backplane provided with the light emitting device comprises:
making the supporting wall in contact with the surface of the backplane provided with the light emitting device, wherein a projection of the supporting wall on the backplane is covered by the non-display area.

4. The manufacturing method of the display panel according to claim 3, wherein the display area is a rectangle, and the supporting wall is a frame shape with a square inner hole.

5. The manufacturing method of the display panel according to claim 3, wherein the display area is circular, and the supporting wall is an annulus with an inner hole.

6. The manufacturing method of the display panel according to claim 2, wherein the supporting wall comprises a base and a filter filled in the base.

7. The manufacturing method of the display panel according to claim 6, wherein a material hardness of the filter is greater than a material hardness of the base.

8. The manufacturing method of the display panel according to claim 6, wherein the filter is one of an irregular particle, a square particle, and a polyhedral particle.

9. The manufacturing method of the display panel according to claim 6, wherein the filter is a sphere.

10. The manufacturing method of the display panel according to claim 9, wherein a spherical diameter of the filter is 0.4 to 0.6 times the predetermined distance.

11. The manufacturing method of the display panel according to claim 10, wherein the spherical diameter of the filter is 0.5 times the predetermined distance.

12. The manufacturing method of the display panel according to claim 6, wherein material of the base comprises epoxy resin, methyl methacrylate, or silica gel, and material of the filter comprises SiO2 or alumina.

13. The manufacturing method of the display panel according to claim 1, wherein a width of a cross section of the supporting wall in a direction perpendicular to the cover gradually decreases from a side close to the cover to another side far away from the cover.

14. The manufacturing method of the display panel according to claim 13, wherein the cross section of the supporting wall in the direction perpendicular to the cover is trapezoidal.

15. The manufacturing method of the display panel according to claim 1, wherein a shape of a cross section of the supporting wall in a direction perpendicular to the cover is one or a combination of a rectangle, a circle, a triangle, a trapezoid, and a T-shape.

16. The manufacturing method of the display panel according to claim 1, wherein the step of providing the backplane, wherein the light emitting device is disposed on the surface of the backplane, comprising:
providing a substrate, wherein the substrate comprises a first surface;
disposing a thin film transistor layer on the first surface to form the backplane; and
disposing the light emitting device on a surface of the thin film transistor layer facing away from the first surface.

17. The manufacturing method of the display panel according to claim 16, wherein the light emitting device is a mini-light-emitting-diode (LED) chip or a micro-LED chip.

18. The manufacturing method of the display panel according to claim 16, wherein the thin film transistor layer has a top gate structure.

19. A manufacturing method of a splicing screen, comprising: the manufacturing method of the display panel as claimed in claim 1, and further comprising steps of:
removing the supporting wall after forming the display panel to form a borderless display panel; and
splicing a plurality of borderless display panels to form the splicing screen.

20. (canceled)

21. A display device, wherein the display device is manufactured by using the manufacturing method of the display panel as claimed in claim 1.
